(19) United States
(12) Patent Application Publication
(10) Pub. No.: US 2021/0273406 A1
(43) Pub. Date: Sep. 2, 2021

(54) OPTICAL TRANSCEIVER AND METHOD OF SETTING WAVELENGTH OF OPTICAL TRANSCEIVER

(71) Applicant: ELECTRONICS AND TELECOMMUNICATIONS RESEARCH INSTITUTE, Daejeon (KR)

(72) Inventors: Jie Hyun Lee, Daejeon (KR); Sae-Kyoung Kang, Daejeon (KR); Joon Ki Lee, Sejong-si (KR); Sun Hyok Chang, Daejeon (KR); Joon Young Huh, Daejeon (KR)

(21) Appl. No.: 16/907,682

(22) Filed: Jun. 22, 2020

(30) Foreign Application Priority Data
Feb. 28, 2020 (KR) 10-2020-0025321

(51) Int. Cl. H01S 5/06; H01S 5/40; H01S 5/0687; H04B 10/40; H04B 10/50

(52) U.S. Cl. CPC H01S 5/0612; H01S 5/4087; H04J 14/02; H04B 10/40; H04B 10/503; H01S 5/0687

(57) ABSTRACT

An optical transceiver and a method of setting a wavelength of the optical transceiver. The optical transceiver may include a thermoelectric cooler (TEC) configured to maintain a constant operating temperature of a transmitter optical sub-assembly (TOSA) of the optical transceiver based on an installation environment of the optical transceiver, a plurality of laser diodes arranged on the top of the TEC and configured to output optical signals having different wavelengths, an optical multiplexer configured to multiplex the optical signals having different wavelengths, output through the plurality of laser diodes, and a wavelength controller configured to control the wavelengths of the optical signals output through the plurality of laser diodes such that optical outputs of the optical signals having different wavelengths, detected through the optical multiplexer, are maximized, wherein the wavelength controller may be individually arranged in one region of each of the plurality of laser diodes.

### CROSS-REFERENCE TO RELATED APPLICATION(S)

This application claims the benefit of Korean Patent Application No. 10-2020-0025321, filed on Feb. 28, 2020, in the Korean Intellectual Property Office, the disclosure of which is incorporated herein by reference.

### BACKGROUND

### 1. Field of the Invention

One or more example embodiments relate to an optical transceiver and, more particularly, to an optical transceiver for increasing a transmission capacity by multiplexing optical signals having different wavelengths.

### 2. Description of Related Art

Recently, there have been continuous demands for high-speed and large-capacity networks based on optical communication due to the general use of smartphones and social networks. In relation to ethernet signals for the Internet, since the 10G Ethernet was standardized in 2002, the 40G/100G standard has been established, and recently the 200G/400G standard has also been developed. Such a large-capacity optical transceiver is implemented in a manner of multiplexing a plurality of optical signals. For example, when four 25G electrical signals are input into a module, a 100G Ethernet optical transceiver converts the signals into 4-channel optical signals having LAN-WDM wavelengths standardized by IEEE and transmits the optical signals using a single optical fiber by performing wavelength division multiplexing on the optical signals of the four wavelengths through an optical multiplexer.

To increase the transmission capacity per wavelength, the 200G/400G standard adopted a technique for doubling the transmission capacity per channel by designating a pulse amplitude modulation (PAM) optical signal as a new standard method. That is, the details of the standard are specified such that a 200G/400G optical transceiver receives four 50G electrical signals or eight 50G electrical signals, converts the signals into optical signals, and transmits the optical signals.

Terabit Ethernet of at least 800G has not been standardized yet, but it is expected that the standard will be developed to increase the transmission capacity of the optical transceiver, by combining a method of increasing the transmission capacity per wavelength and a method of increasing the number of wavelength channels to be multiplexed. In this case, an available wavelength band is limited, and thus it is expected that the wavelength channel spacing becomes denser than before, and a laser diode having a precise output wavelength is required for this.

The output wavelength of the laser diode is determined based on the period of a diffraction grating that determines a resonance period. Therefore, if the period of the diffraction grating is not accurately patterned in a process of manufacturing a chip for the laser diode, the output wavelength of the laser diode may have some errors from a designed value. In this case, an error in the output wavelength occurring in a process of manufacturing a laser diode may be compensated for by changing the output wavelength by raising or lowering the operating temperature using a thermoelectric cooler (TEC) used to maintain a constant operating temperature of the laser diode.

However, when there are multiple wavelength channels to be multiplexed, changing the operating temperature of the laser causes a change in the wavelengths of several semiconductor laser diodes in the same direction at the same time. Thus, it is not suitable for correcting patterning errors occurring during the process of manufacturing a chip for a laser diode.

### SUMMARY

An aspect provides a method and apparatus for separately controlling wavelengths of optical signals output through a plurality of laser diodes arranged on the same thermoelectric cooler (TEC) by arranging a wavelength controller, such as a heat source, in each of the plurality of laser diodes constituting a transmitter optical sub-assembly (TOSA) of an optical transceiver.

Another aspect provides a method and apparatus for easily verifying whether optical signals output through a plurality of laser diodes are multiplexed through a passband of an optical multiplexer of a TOSA, by arranging a photodiode at the rear end of the optical multiplexer.

According to an aspect, there is provided an optical transceiver including a TEC configured to maintain a constant operating temperature of a TOSA of the optical transceiver based on an installation environment of the optical transceiver, a plurality of laser diodes arranged on the top of the TEC and configured to output optical signals having different wavelengths, an optical multiplexer configured to multiplex the optical signals having different wavelengths, output through the plurality of laser diodes, and a wavelength controller configured to control the wavelengths of the optical signals output through the plurality of laser diodes such that optical outputs of the optical signals having different wavelengths, detected through the optical multiplexer, are maximized, wherein the wavelength controller may be individually arranged in one region of each of the plurality of laser diodes.

The wavelength controller may be configured to control the wavelengths of the optical signals output through the laser diodes by adjusting temperatures of the laser diodes through heat sources.

The optical transceiver may further include a photodiode arranged at the rear end of the optical multiplexer and configured to detect optical output of the optical signals having different wavelengths, detected through the optical multiplexer.

The photodiode may be configured to periodically or aperiodically sense whether the optical signals having different wavelengths are normally detected through the optical multiplexer.

According to another aspect, there is provided a method of setting a wavelength of a TOSA, the method performed by a processor of an optical transceiver, the method including setting a temperature of a TEC to maintain a constant operating temperature of a TOSA of the optical transceiver based on an installation environment of the optical transceiver, setting drive conditions for a plurality of laser diodes arranged on the top of the TEC and configured to output optical signals having different wavelengths, verifying, using a photodiode according to the set drive conditions, whether the optical signals having different wavelengths, output through the plurality of laser diodes, are detected through an optical multiplexer, and controlling, if the optical signals having different wavelengths are detected through the optical multiplexer, a wavelength controller individually arranged in one region of each of the plurality of laser diodes such that optical outputs of the detected optical signals are maximized.

The wavelength controller may be configured to control the wavelengths of the optical signals output through the laser diodes by adjusting temperatures of the laser diodes through heat sources.

The controlling may include resetting the temperature of the TEC, if at least one of the optical signals having different wavelengths is not detected through the optical multiplexer.

The verifying may include periodically or aperiodically sensing, using the photodiode, whether the optical signals having different wavelengths are normally detected through the optical multiplexer.

According to example embodiments, it is possible to separately control wavelengths of optical signals output through a plurality of laser diodes arranged on the same thermoelectric cooler (TEC) by arranging a wavelength controller, such as a heat source, in each of the plurality of laser diodes constituting a transmitter optical sub-assembly (TOSA) of an optical transceiver.

According to example embodiments, it is possible to easily verify whether optical signals output through a plurality of laser diodes are multiplexed through a passband of an optical multiplexer of a TOSA, by arranging a photodiode at the rear end of the optical multiplexer, and thus it is possible to reduce the cost for manufacturing/testing and operating a large-capacity optical transceiver.

Additional aspects of example embodiments will be set forth in part in the description which follows and, in part, will be apparent from the description, or may be learned by practice of the disclosure.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a block diagram illustrating an optical transceiver according to an example embodiment;

FIG. 2 illustrates an example of an optical transceiver according to an example embodiment; and

FIG. 3 is a flowchart illustrating a method of setting a wavelength of an optical transceiver according to an example embodiment.

### DETAILED DESCRIPTION OF THE INVENTION

Hereinafter, example embodiments will be described in detail with reference to the accompanying drawings.

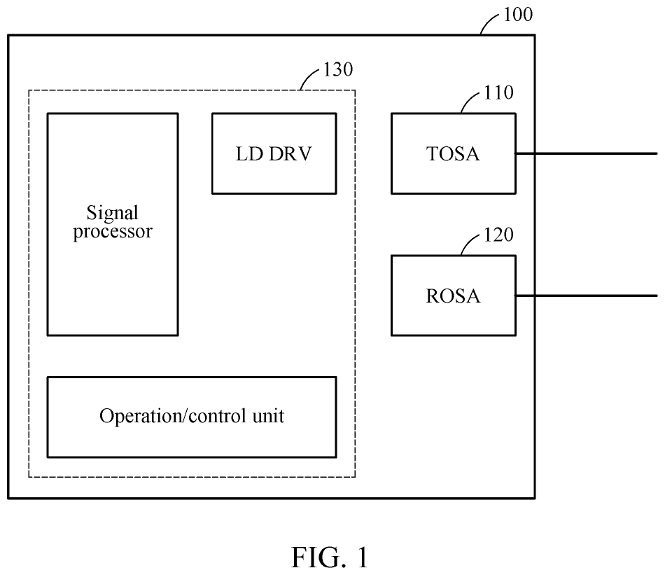

FIG. 1 is a block diagram illustrating an optical transceiver according to an example embodiment.

Referring to FIG. 1, a optical transceiver 100 includes a transmitter optical sub-assembly (TOSA) 110, a receiver optical sub-assembly (ROSA) 120, and a processing module 130 for driving the TOSA and the ROSA. In this example, the optical transceiver 100 may maintain the TOSA 110 at a constant temperature using a thermoelectric cooler (TEC) to prevent a change in optical power characteristic and transmission performance according to a temperature change in an environment where the optical transceiver 100 is used.

The optical transceiver 100 may include the TOSA 110 that multiplexes optical signals having different wavelengths and outputs the optical signals through a single optical fiber, and the ROSA 120 that receives the optical signals having the multiplexed wavelengths, and demultiplexes and converts the optical signals into electrical signals, to increase the transmission capacity.

In this example, an optical multiplexer that multiplexes the optical signals having different wavelengths may be arranged in the TOSA 110, and a demultiplexer that demultiplexes the optical signals having the multiplexed wavelengths may be arranged in the ROSA 120. Thus, there may be an issue of wavelength alignment.

That is, the TOSA 110 may obtain outputs of a plurality of laser diodes arranged in the TOSA 110 through the optical multiplexer. Thus, if the wavelengths of the plurality of laser diodes are not aligned in a passband of the optical multiplexer, an attenuated optical output may be obtained, rather than the maximum optical output. Thus, the TOSA 110 requires a method of controlling the output wavelengths of the laser diodes to obtain the maximum optical output. Such wavelength alignment is an increasingly important issue in the large-capacity optical transceiver 100 with a dense wavelength channel spacing between the plurality of optical signals.

The TOSA 110 used in the optical transceiver 100 may use a scheme of directly modulating a laser diode, such as DFB-LD, VCSEL, or DBR-LD, or a scheme of externally modulating an optical output of a laser diode using an electro-absorption modulator (EAM) or a Mach-Zehnder modulator (MZM). The output wavelength of the optical transceiver 100 may be determined by a laser diode, irrespective of the modulation scheme of the TOSA 110, in detail, may be determined by the period of a diffraction grating that determines a resonance period of the laser diode.

Therefore, if the period of the diffraction grating is not accurately patterned in a process of manufacturing a chip for the laser diode, the output wavelength of the laser diode may have some errors compared to a designed value.

Further, as the processing module 130 applies a drive current or a drive voltage to the TOSA 110 to operate the TOSA 110, the output wavelength of the laser diode may be changed by a temperature change in a laser active layer of a semiconductor.

To correct a change in the output wavelength of the optical transmission module 110 that may be caused by various factors, a method of correcting a portion of the change in the output wavelength by artificially raising or lowering the operating temperature of the laser diode arranged in the TOSA 110 using a TEC was used in the past.

However, since laser diodes outputting optical signals having different wavelengths are arranged on a single TEC, there may be a limit in adjusting the output wavelength using the TEC. In addition, if the wavelength channel spacing corresponding to the laser diodes is dense, adjusting the output wavelength of a specific channel using the TEC may cause a distortion of the output wavelength of another channel.

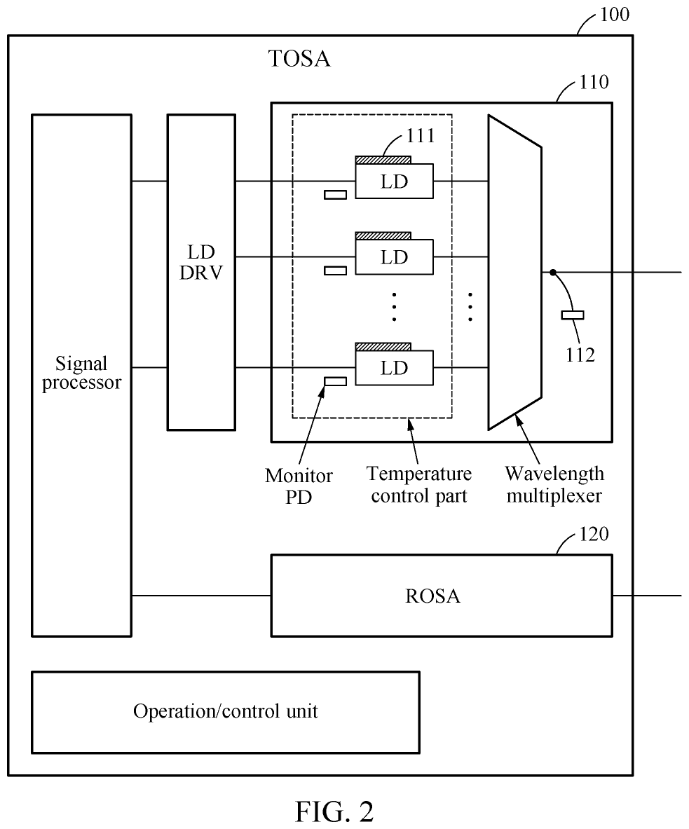

FIG. 2 illustrates an example of an optical transceiver according to an example embodiment.

As described above, if a plurality of laser diodes are disposed on a single TEC, increasing or decreasing the temperature of the TEC affects all of the plurality of laser diodes, and thus it may be difficult to adjust the output wavelength of a predetermined channel.

To solve this problem, a wavelength controller 111, such as a heat source, may be individually disposed in each of the plurality of laser diodes arranged in the TOSA 110 of the optical transceiver 100, as shown in FIG. 2. In this example, the individually arranged wavelength controller may individually control an output wavelength of an optical signal output through a corresponding laser diode by changing the temperature of each of the plurality of laser diodes disposed on the same TEC.

More specifically, the wavelength controller 111 may arrange a metal on a partial region of the top of a Bragg grating that determines the output wavelength of the laser diode, and change the Bragg grating by applying heat to the arranged metal, thereby changing the output wavelength of the laser diode.

Further, the optical transceiver 100 may be manufactured in a structure in which a portion of the output of the optical multiplexer is tabbed and connected to a photodiode (PD) 112. The photodiode 112 may sense the strength of an optical output detected through the optical multiplexer and thus, may sense the wavelength.

By arranging the photodiode 112 in the TOSA 110, the optical transceiver 100 may easily verify whether the output wavelengths of optical signals output through the TOSA 110 are output normally through the optical multiplexer, through a process of power ON/OFF with respect to an individual laser diode. This process may be performed in a process of supplying the optical transceiver 100 with power for the first time, or may be periodically performed in an idle state.

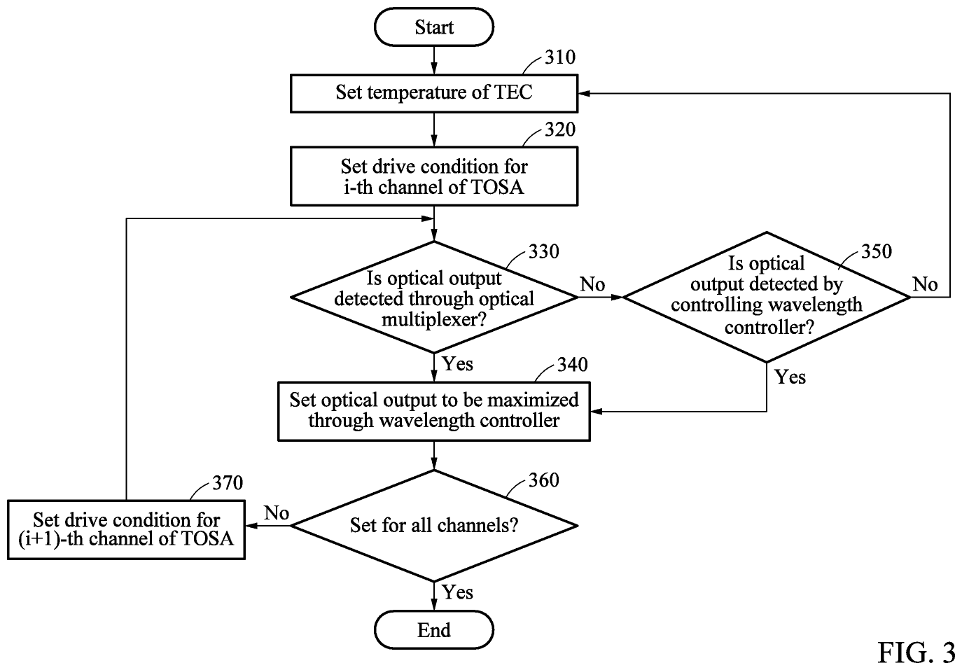

FIG. 3 is a flowchart illustrating a method of setting a wavelength of an optical transceiver according to an example embodiment.

In operation 310, the processing module 130 of the optical transceiver 100 may set a temperature of a TEC to maintain a constant operating temperature of the TOSA 110, considering an environment where the large-capacity optical transceiver 100 is to be installed.

In operation 320, the processing module 130 may set drive conditions for a plurality of laser diodes arranged on the top of the TEC and configured to output optical signals having different wavelengths. In this example, the processing module 130 may set the drive conditions for the plurality of laser diodes, sequentially one at a time.

The drive conditions for the laser diodes may be voltages or currents depending on the type of the TOSA 110, and may be both a direct current (DC) bias signal and an alternating current (AC) signal. These signals may be applied separately, or may be applied concurrently through a chip such as a laser diode driver (LD DRV). For example, a multi-level signal such as PAM-4 may be applied.

In operation 330, the processing module 130 may verify, using the photodiode 112 according to the set drive conditions, whether the optical signals having different wavelengths, output through the plurality of laser diodes, are detected through an optical multiplexer. In detail, an alignment state with respect to the output wavelength of the TOSA 110 may be verified through the strength of the optical output detected through the optical multiplexer. Thus, the processing module 130 may need to individually check the wavelength alignment state by selecting a predetermined channel from among the plurality of laser diodes.

If an optical output with respect to an optical signal output through a laser diode corresponding to a predetermined channel is detected through the optical multiplexer according to a set drive condition, the processing module 130 may control the wavelength controller 111 arranged in a region of the laser diode corresponding to the predetermined channel to maximize the detected optical output with respect to the optical signal, in operation 340.

Conversely, if an optical output with respect to the optical signal output through the laser diode is not detected through the optical multiplexer according to the set drive condition, the processing module 130 may determine whether the optical output is detected by controlling the wavelength controller 111 arranged in a region of a laser diode corresponding to the predetermined channel, in operation 350. In this example, in response to the determination that the optical output is detected, the processing module 130 may control the wavelength controller 111 of the laser diode corresponding to the predetermined channel to set the detected optical output to be maximized, in operation 340. Conversely, in response to the determination that the optical output is not detected, the processing module 130 may return to operation 410 to reset the temperature of the TEC and then repeat the subsequent operations.

After that, in operation 360, the processing module 130 may determine whether drive conditions for laser diodes corresponding to all channels are set, and terminate the wavelength setting in response to the determination that the setting is completed. Conversely, in response to the determination that the setting is not completed yet, the processing module 130 may turn off the laser diode of which the drive condition is set immediately before, and determine whether an optical output is detected through the optical multiplexer by setting a drive condition for a subsequent laser diode, in operation 370.

Meanwhile, in the case of adjusting the set value of the TEC in the process of setting the wavelengths with respect to the laser diodes of the plurality of channels constituting the optical transceiver 100, the processing module 130 may need to individually verify whether the optical outputs are still detected by the drive conditions preset for the laser diodes of which the wavelengths are already completed and the set values of the wavelength controller 111.

As described above, the optical transceiver 100 may separately control output wavelengths of optical signals output through a plurality of laser diodes, by arranging the wavelength controller 111 such as a heat source in each of the plurality of laser diodes constituting the TOSA 110, even on the same TEC. Through this, it is possible to increase the price competitiveness of the optical transceiver 100 by adjusting and using the output wavelengths of the laser diodes even in optical links having a dense wavelength channel spacing.

Further, the optical transceiver 100 may easily verify whether output wavelengths of a plurality of optical signals output through a plurality of laser diodes are multiplexed through a passband of an optical multiplexer, by additionally arranging a photodiode at the rear end of the optical multiplexer of the TOSA 110.

The components described in the example embodiments may be implemented by hardware components including, for example, at least one digital signal processor (DSP), a processor, a controller, an application-specific integrated circuit (ASIC), a programmable logic element, such as a field programmable gate array (FPGA), other electronic devices, or combinations thereof. At least some of the functions or the processes described in the example embodiments may be implemented by software, and the software may be recorded on a recording medium. The components, the functions, and the processes described in the example embodiments may be implemented by a combination of hardware and software.

In the meantime, the method according to an example embodiment may be implemented as various recording media such as a magnetic storage medium, an optical read medium, and a digital storage medium after being implemented as a program that can be executed in a computer.

The implementations of the various technologies described in the specification may be implemented with a digital electronic circuit, computer hardware, firmware, software, or the combinations thereof. The implementations may be achieved as a computer program product, for example, a computer program tangibly embodied in a machine readable storage device (a computer-readable medium) to process the operations of a data processing device, for example, a programmable processor, a computer, or a plurality of computers or to control the operations. The computer programs such as the above-described computer program(s) may be recorded in any form of a programming language including compiled or interpreted languages, and may be executed as a standalone program or in any form included as another unit suitable to be used in a module, component, sub routine, or a computing environment. The computer program may be executed to be processed on a single computer or a plurality of computers at one site or to be distributed across a plurality of sites and then interconnected by a communication network.

The processors suitable to process a computer program include, for example, both general purpose and special purpose microprocessors, and any one or more processors of a digital computer of any kind. Generally, the processor may receive instructions and data from a read only memory, a random access memory or both of a read only memory and a random access memory. The elements of a computer may include at least one processor executing instructions and one or more memory devices storing instructions and data. In general, a computer may include one or more mass storage devices storing data, such as a magnetic disk, a magneto-optical disc, or an optical disc or may be coupled with them so as to receive data from them, to transmit data to them, or to exchange data with them. For example, information carriers suitable to embody computer program instructions and data include semiconductor memory devices, for example, magnetic Media such as hard disks, floppy disks, and magnetic tapes, optical Media such as compact disc read only memory (CD-ROM), and digital video disc (DVD), magneto-optical media such as floppy disks, ROM, random access memory (RAM), flash memory, erasable programmable ROM (EPROM), electrically erasable programmable ROM (EEPROM), and the like. The processor and the memory may be supplemented by a special purpose logic circuit or may be included by the special purpose logic circuit.

Furthermore, the computer-readable medium may be any available medium capable of being accessed by a computer and may include a computer storage medium.

Although the specification includes the details of a plurality of specific implementations, it should not be understood that they are restricted with respect to the scope of any invention or claimable matter. On the contrary, they should be understood as the description about features that may be specific to the specific example embodiment of a specific invention. Specific features that are described in this specification in the context of respective example embodiments may be implemented by being combined in a single example embodiment. On the other hand, the various features described in the context of the single example embodiment may also be implemented in a plurality of example embodiments, individually or in any suitable sub-combination. Furthermore, the features operate in a specific combination and may be described as being claimed. However, one or more features from the claimed combination may be excluded from the combination in some cases. The claimed combination may be changed to sub-combinations or the modifications of sub-combinations.

Likewise, the operations in the drawings are described in a specific order. However, it should not be understood that such operations need to be performed in the specific order or sequential order illustrated to obtain desirable results or that all illustrated operations need to be performed. In specific cases, multitasking and parallel processing may be advantageous. Moreover, the separation of the various device components of the above-described example embodiments should not be understood as requiring such the separation in all example embodiments, and it should be understood that the described program components and devices may generally be integrated together into a single software product or may be packaged into multiple software products.

In the meantime, example embodiments of the present invention disclosed in the specification and drawings are simply the presented specific example to help understand an example embodiment of the present invention and not intended to limit the scopes of example embodiments of the present invention. It is obvious to those skilled in the art that other modifications based on the technical idea of the present invention may be performed in addition to the example embodiments disclosed herein.

What is claimed is:

1. An optical transceiver comprising:
a thermoelectric cooler (TEC) configured to maintain a constant operating temperature of a transmitter optical sub-assembly (TOSA) of the optical transceiver based on an installation environment of the optical transceiver;
a plurality of laser diodes arranged on the top of the TEC and configured to output optical signals having different wavelengths;
an optical multiplexer configured to multiplex the optical signals having different wavelengths, output through the plurality of laser diodes; and
a wavelength controller configured to control the wavelengths of the optical signals output through the plurality of laser diodes such that optical outputs of the optical signals having different wavelengths, detected through the optical multiplexer, are maximized,
wherein the wavelength controller is individually arranged in one region of each of the plurality of laser diodes.

2. The optical transceiver of claim 1, wherein the wavelength controller is configured to control the wavelengths of the optical signals output through the laser diodes by adjusting temperatures of the laser diodes through heat sources.

3. The optical transceiver of claim 1, further comprising:
a photodiode arranged at the rear end of the optical multiplexer and configured to detect optical output of the optical signals having different wavelengths, detected through the optical multiplexer.

4. The optical transceiver of claim 3, wherein the photodiode is configured to periodically or aperiodically sense whether the optical signals having different wavelengths are normally detected through the optical multiplexer.

5. A method of setting a wavelength of a transmitter optical sub-assembly (TOSA), the method performed by a processor of an optical transceiver, the method comprising:
setting a temperature of a TEC to maintain a constant operating temperature of a TOSA of the optical transceiver based on an installation environment of the optical transceiver;
setting drive conditions for a plurality of laser diodes arranged on the top of the TEC and configured to output optical signals having different wavelengths;
verifying, using a photodiode according to the set drive conditions, whether the optical signals having different wavelengths, output through the plurality of laser diodes, are detected through an optical multiplexer; and
controlling, if the optical signals having different wavelengths are detected through the optical multiplexer, a wavelength controller individually arranged in one region of each of the plurality of laser diodes such that optical outputs of the detected optical signals are maximized.

6. The method of claim 5, wherein the wavelength controller is configured to control the wavelengths of the optical signals output through the laser diodes by adjusting temperatures of the laser diodes through heat sources.

7. The method of claim 5, wherein the controlling comprises resetting the temperature of the TEC, if at least one of the optical signals having different wavelengths is not detected through the optical multiplexer.

8. The method of claim 5, wherein the verifying comprises periodically or aperiodically sensing, using the photodiode, whether the optical signals having different wavelengths are normally detected through the optical multiplexer.
